(19) United States
(12) Patent Application Publication
(10) Pub. No.: US 2026/0114077 A1
(43) Pub. Date: Apr. 23, 2026

(54) PHOTODIODE AND MANUFACTURING METHOD THEREOF

(71) Applicant: Taiwan-Asia Semiconductor Corporation, Hsinchu City (TW)

(72) Inventor: Yu-Hsin Liu, Hsinchu City (TW)

(21) Appl. No.: 19/076,747

(22) Filed: Mar. 11, 2025

(30) Foreign Application Priority Data
Oct. 21, 2024 (TW) 113139994

(51) Int. Cl. H10F 77/30; H10F 71/00

(52) U.S. Cl. CPC H10F 77/334; H10F 71/136; H10F 77/306; H10F 77/337

(57) ABSTRACT

A photodiode and a manufacturing method thereof are provided. The manufacturing method of the photodiode comprises the following steps: providing a wafer with a plurality of photodiode structures, attaching a protective film to the wafer, cutting the protective film and the wafer to form a plurality of cutting lanes on the protective film and the wafer to separate each photodiode structure, coating a light-shielding solution on the protective film so that the light-shielding solution covers each cutting lane, and curing the light-shielding solution so that a light-shielding sidewall are formed to completely cover the sidewall of each photodiode structure to block any light from penetrating the sidewall.

### CROSS-REFERENCES TO RELATED APPLICATIONS

This application claims the benefit of priority to Taiwanese Patent Application No. 113139994 filed on Oct. 21, 2024, which is hereby incorporated by reference in its entirety.

### BACKGROUND OF THE INVENTION

### Field of the Invention

The present invention relates to a photodiode and a manufacturing method thereof, in particular to a photodiode having light-shielding sidewalls and a manufacturing method thereof.

### Descriptions of the Related Art

A photodiode is an electronic device designed to convert external optical signals into electrical signals. The core function of a photodiode lies in its ability to absorb external light for enabling the detection of optical signals and their conversion into measurable current. This conversion is critical for various applications, such as optical communication, optical measurement, and image generation.

The mechanism by which photodiodes absorb external light relies on the semiconductor material within the diode (e.g., silicon substrate). When photons enter the photodiode and are absorbed, their energy excites electrons in the valence band to transition to the conduction band for generating electron-hole pairs. These photo-generated carriers are separated under the influence of the diode's built-in electric field and an electric current is generated correspondingly.

However, in traditional photodiodes, external light can easily penetrate the exposed sidewalls of the device and interfere with the internal operation of the device. This interference can degrade the linearity of the photodiode device and introduce computational errors in the following applications. To address this issue, there is an urgent need for an innovative photodiode structure that mitigates the error signals caused by external light penetrating the sidewalls of the device.

### SUMMARY OF THE INVENTION

The main objective of the present invention is to provide an innovative photodiode and its manufacturing method. Compared to conventional photodiode devices, the photodiode of this invention features light-shielding sidewalls that prevent external light from entering the device's interior. This design enhances the linearity of the photodiode's response and reduces issues arising from erroneous signals generated in the following procedures operated by the device.

To achieve the above objective, the present invention discloses a manufacturing method of the photodiode comprises the following steps: providing a wafer with a plurality of photodiode structures, attaching a protective film to the wafer, cutting the protective film and the wafer to form a plurality of cutting lanes on the protective film and the wafer to separate each photodiode structure, coating a light-shielding solution on the protective film so that the light-shielding solution covers each cutting lane, and curing the light-shielding solution so that a light-shielding sidewall are formed to completely cover the sidewall of each photodiode structure to block any light from penetrating the sidewall.

In one embodiment of a method of manufacturing a photodiode of the present invention, the step of providing a wafer is to provide a wafer having a plurality of photodiode structures and each of the photodiode structures includes a substrate, an intrinsic area and a filter layer, wherein the intrinsic area is disposed on the substrate, and the filter layer is disposed over the intrinsic area and is configured to selectively allow only light of a specific wavelength to pass through and be received by the intrinsic area so an electrical signal is generated correspondingly.

In one embodiment of a method of manufacturing a photodiode of the present invention, the step of forming a plurality of cutting lanes further includes a step of stretching the protective film to expand the distance between the cutting lanes.

In one embodiment of a method of manufacturing a photodiode of the present invention, the step of expanding the distance between the cutting lanes is a step of forming a spacing between the cutting lanes of 0.1 to 0.5 millimeters (mm).

In one embodiment of a method of manufacturing a photodiode of the present invention, the step of coating a light-shielding solution is a step of coating an epoxy resin solution.

In one embodiment of a method of manufacturing a photodiode of the present invention, the method further comprises a step of laser cutting each of the cutting lanes after the step of curing the light-shielding solution.

In one embodiment of a method of manufacturing a photodiode of the present invention, the method further comprises a step of providing an ultraviolet light to irradiate the protective film to separate the protective film and the wafer and form a plurality of photodiodes.

To achieve the above objective, the present invention discloses a photodiode, comprising a photodiode structure and a light-shielding sidewall. The photodiode structure includes a first conductive type substrate, an intrinsic area, a second conductivity type semiconductor layer and a filter layer. The intrinsic area is disposed on the first conductive type substrate. The second conductivity type semiconductor layer is disposed on the intrinsic area. The filter layer is disposed over the second conductivity type semiconductor layer and configured to selectively allow only light of a specific wavelength to pass through and be received by the intrinsic area so an electrical signal is generated correspondingly. The light-shielding sidewall completely covers a sidewall of the photodiode structure to block any light from passing through the sidewall and being received by the intrinsic area.

In one embodiment of a photodiode of the present invention, the light-shielding sidewall is an epoxy resin sidewall.

In one embodiment of a photodiode of the present invention, the light of a specific wavelength is an ultraviolet light.

In one embodiment of a photodiode of the present invention, the wavelength of the ultraviolet light is smaller than 400 nanometers (nm).

In one embodiment of a photodiode of the present invention, the filter layer is a band pass filer layer.

In one embodiment of a photodiode of the present invention, the photodiode further comprises an anti-reflective layer formed above the filter layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 illustrates an enlarged cross-sectional schematic diagram of a wafer and one photodiode structure on the wafer in an embodiment of the present invention.

FIG. 2 illustrates a schematic diagram of a protective film attached to a wafer in an embodiment of the present invention.

FIG. 3 illustrates a cross-sectional schematic diagram of a protective film attached to a photodiode structure in an embodiment of the present invention.

FIG. 4 illustrates a schematic diagram of a cutting wheel used to cut the protective film and the wafer in an embodiment of the present invention.

FIG. 5 illustrates a top view schematic diagram of cutting lanes on the wafer surface in an embodiment of the present invention.

FIG. 6 illustrates a cross-sectional schematic diagram of two adjacent photodiode structures in an embodiment of the present invention.

FIG. 7 illustrates a schematic diagram of applying a light-shielding solution to the wafer surface in an embodiment of the present invention.

FIG. 8 illustrates a partial cross-sectional schematic diagram along line AA′ in FIG. 7.

FIG. 9 illustrates a schematic diagram of a photodiode in an embodiment of the present invention.

FIG. 10 illustrates a flowchart of the manufacturing steps for the photodiode in an embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

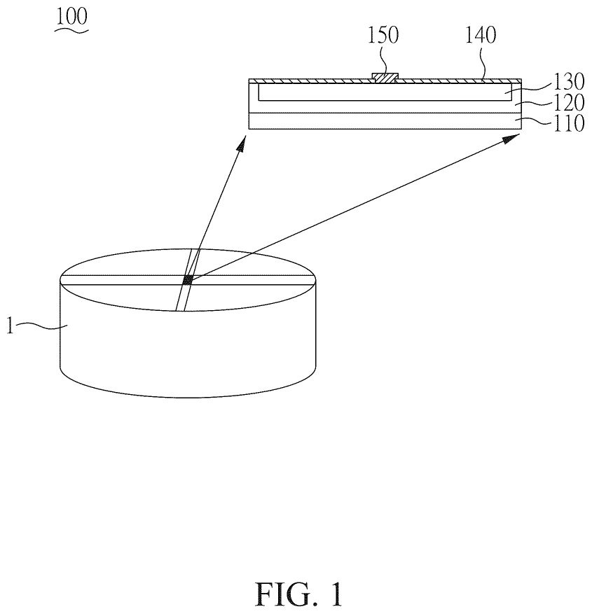

Please refer to FIG. 1, which illustrates an enlarged cross-sectional schematic diagram of a wafer and one photodiode structure on the wafer in an embodiment of the present invention. As shown, in this embodiment, the wafer 1 is a silicon wafer. The wafer 1 contains a plurality of uncut photodiode structures 100, each of which includes a first conductive-type substrate 110, an intrinsic region 120, a second conductive-type semiconductor layer 130, a filter layer 140, and an electrode 150. The first conductive type substrate 110 is an N-type doped semiconductor layer, such as, but not limited to, silicon-doped gallium nitride (GaN) or silicon carbide (SiC). The intrinsic region 120 is disposed on the first conductive type substrate 110, covering it. The intrinsic region 120 is an undoped or lightly doped semiconductor layer, such as, but not limited to, aluminum gallium nitride (AlGaN), gallium nitride (GaN), or silicon carbide (SiC). It is designed to receive light of specific wavelengths, such as ultraviolet light with wavelengths less than 400 nanometers (nm), and generate corresponding electrical signals. The second conductive type semiconductor layer 130, which is disposed on the intrinsic region 120, is a P-type doped semiconductor layer, such as, but not limited to, magnesium-doped gallium nitride (GaN) or aluminum gallium nitride (AlGaN).

Additionally, the filter layer 140 is typically a band-pass filter layer covering the second conductive type semiconductor layer 130. It selectively permits light of a specific wavelength, such as ultraviolet light with wavelengths less than 400 nm, to pass through to the intrinsic region 120 while blocking light of other wavelengths, such as visible or infrared light. The filter layer 140 is usually composed of multiple layers of dielectric materials with alternating high and low refractive indices, such as silicon dioxide (SiO₂), titanium dioxide (TiO₂), or silicon nitride (Si₃N₄). In a preferred embodiment, an anti-reflective layer (not shown) may be formed on the filter layer 140 to enhance transmittance for specific wavelengths, maximize photon utilization, and minimize reflection losses of incident light for thereby improving the photoelectric conversion efficiency of the device. The electrode 150 is disposed on and electrically connected to the second conductive type semiconductor layer 130. This electrode 150 may be, but not limited to, aluminum metal.

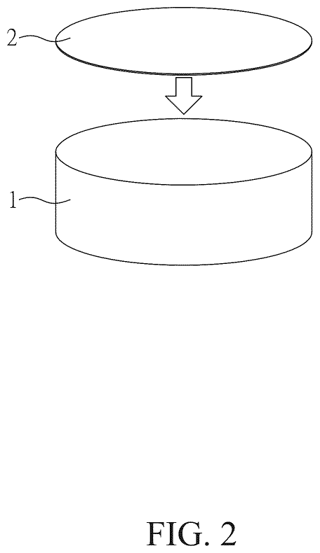

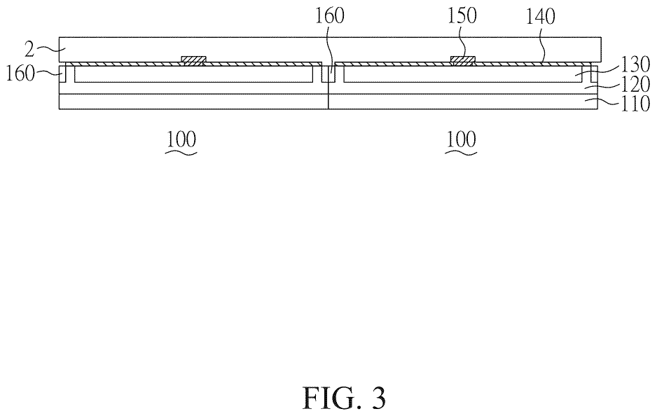

Please also refer to FIG. 2 and FIG. 3, which show the attachment of a protective film 2 to the wafer 1. The protective film 2 is a UV-dicing tape. Its characteristics include high adhesion during use for making it resistant to detachment, while the adhesion of the protective film will be reduced after ultraviolet light exposure for facilitating easy detachment without adhesive residue. As shown in FIG. 3, the wafer 1 includes inactive regions 160 between two adjacent photodiode structures 100. These inactive regions 160 are doped with an N-type dopant to electrically isolate devices on the wafer and serve as cutting lanes for dividing devices in the following division processes.

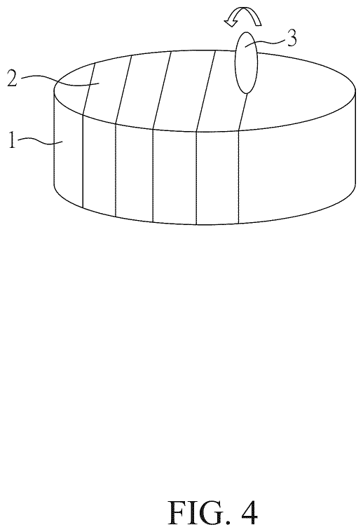

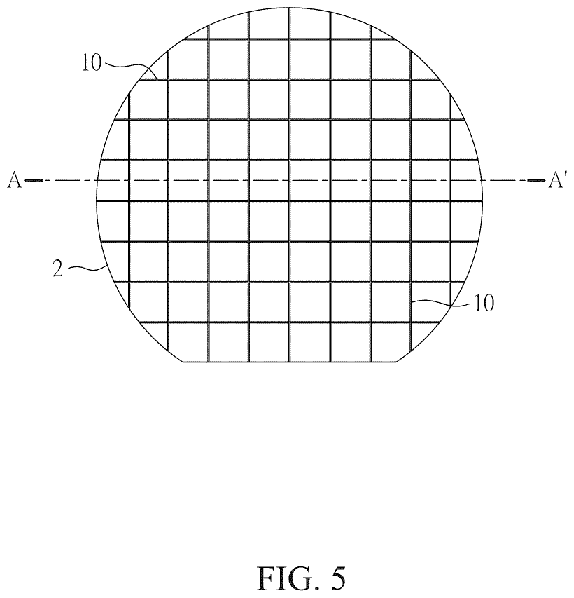

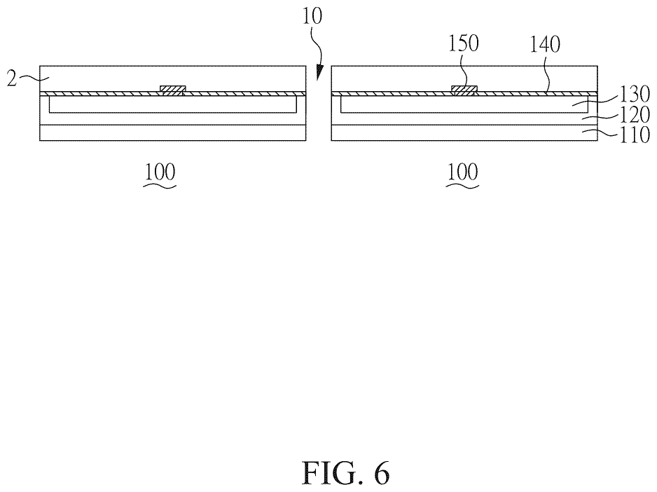

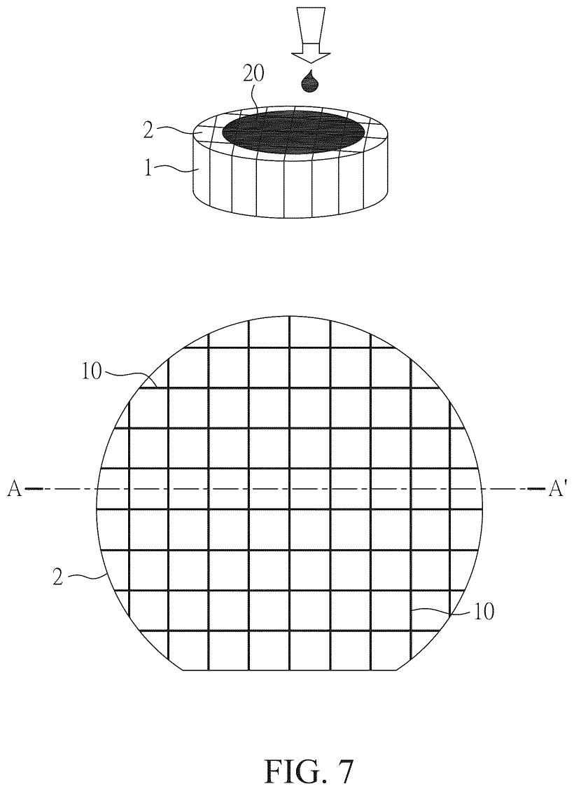

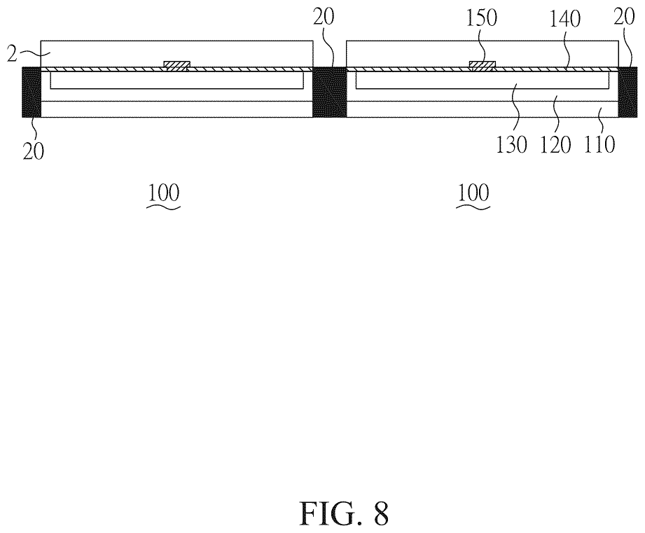

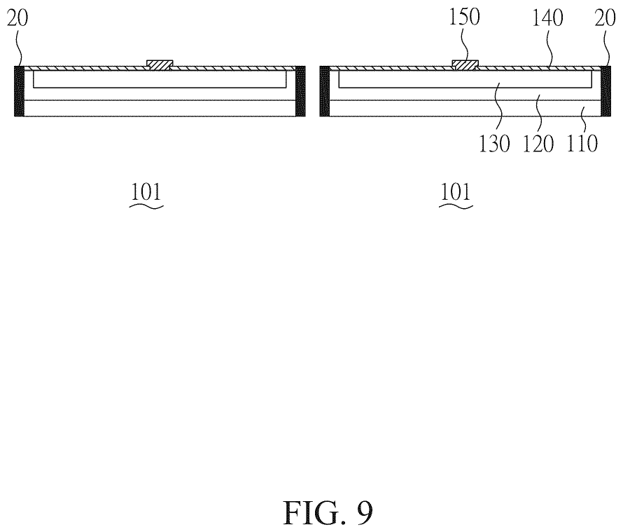

Refer to FIG. 4, FIG. 5, and FIG. 6. FIG. 4 shows a cutting wheel 3 being used to cut the protective film 2 and the inactive regions 160 of the wafer 1 for forming a plurality of cutting lanes 10 on the protective film 2 and the wafer 1 to separate the photodiode structures 100. In a preferred embodiment, after forming the cutting lanes 10, the protective film 2 can be stretched to further expand the spacing between the cutting lanes 10, preferably to a range of 0.1-0.5 millimeters (mm), as shown in FIG. 5. FIG. 6 is a partial cross-sectional schematic along line AA′ in FIG. 5, showing two adjacent photodiode structures 100 divided by cutting lane 10. Next, refer to FIG. 7 and FIG. 8. FIG. 7 shows a light-shielding solution, such as liquid epoxy resin 20, applied over the protective film 2. FIG. 8 is a partial cross-sectional schematic along line AA′ in FIG. 7, showing that the cutting lanes 10 between two adjacent photodiode structures 100 has been filled with liquid epoxy resin 20. After injection liquid epoxy resin, excess epoxy resin is cleaned from the surface of the wafer 1, such as by using a sponge for wiping. The epoxy resin 20 in the cutting lanes 10 is then subjected to a curing process by heating and is solidified. Refer to FIG. 9. Afterward, laser or conventional cutting wheel is employed to cut through the solidified epoxy resin 20 within the cutting lanes 10. Finally, ultraviolet light is applied to the protective film 2 to detach it from the wafer 1 for resulting in the formation of multiple individually separated photodiodes 101.

One characteristic of the photodiode 101 of the present invention focuses on the light-shielding sidewall. This light-shielding sidewall is composed of the opaque epoxy resin 20, which fully covers the edges of photodiode structure 100. It blocks any light from passing through the sidewall to reach the intrinsic region 120 to reduce interference from external side light. Thereby, the linearity of the device's photosensitivity is improved and computational errors in the following operations will be minimized.

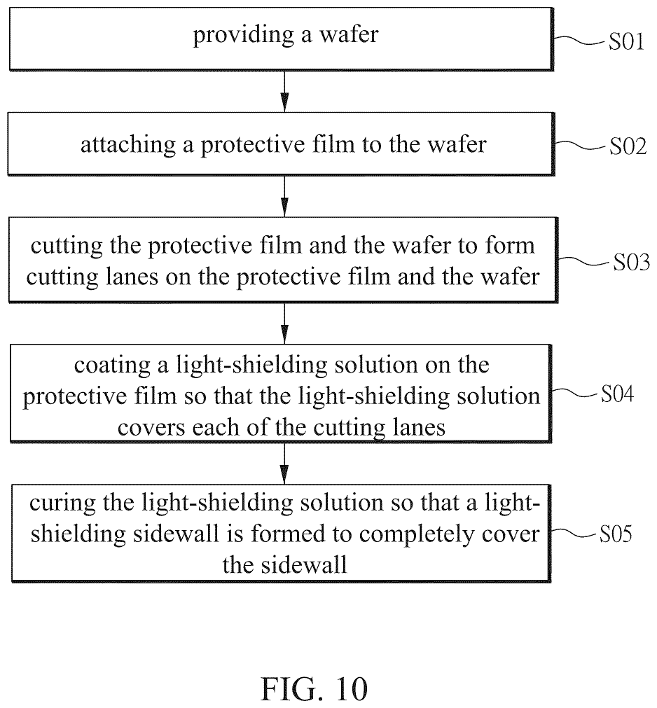

Please refer to FIG. 10, which shows a flowchart of the manufacturing steps for the photodiode of the present invention. First, in step S01, a wafer having a plurality of photodiode structures is provided. In step S02, a protective film is attached to the wafer. In step S03, the protective film and wafer are cut to form a plurality of cutting lanes for separating the photodiode structures. Next, in step S04, a light-shielding solution is applied to the protective film for covering the cutting lanes. Finally, in step S05, the light-shielding solution is cured to form light-shielding sidewalls that completely cover the sidewalls of each photodiode structure for preventing any light from penetrating through the sidewalls. The descriptions of the related components are referenced from the aforementioned content and will not be repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A manufacturing method of a photodiode, comprising:
providing a wafer having a plurality of photodiode structures;
attaching a protective film to the wafer;
cutting the protective film and the wafer to form a plurality of cutting lanes on the protective film and the wafer to separate each of the photodiode structures;
coating a light-shielding solution on the protective film so that the light-shielding solution covers each of the cutting lanes; and
curing the light-shielding solution so that a light-shielding sidewall is formed to completely cover the sidewall of each of the photodiode structures to block any light from penetrating therethrough.

2. The manufacturing method of claim 1, wherein the step of providing a wafer is to provide a wafer having a plurality of photodiode structures and each of the photodiode structures includes a substrate, an intrinsic area and a filter layer, wherein the intrinsic area is disposed on the substrate, and the filter layer is disposed over the intrinsic area and is configured to selectively allow only light of a specific wavelength to pass through and be received by the intrinsic area so an electrical signal is generated correspondingly.

3. The manufacturing method of claim 1, wherein the step of forming a plurality of cutting lanes further includes a step of stretching the protective film to expand the distance between the cutting lanes.

4. The manufacturing method of claim 3, wherein the step of expanding the distance between the cutting lanes is a step of forming a spacing between the cutting lanes of 0.1 to 0.5 millimeters (mm).

5. The manufacturing method of claim 1, wherein the step of coating a light-shielding solution is a step of coating an epoxy resin solution.

6. The manufacturing method of claim 1, further comprising a step of laser cutting each of the cutting lanes after the step of curing the light-shielding solution.

7. The manufacturing method of claim 1, further comprising a step of providing an ultraviolet light to irradiate the protective film to separate the protective film and the wafer and form a plurality of photodiodes.

8. A photodiode, comprising:
a photodiode structure, including
a first conductive type substrate;
an intrinsic area disposed on the first conductive type substrate;
a second conductivity type semiconductor layer disposed on the intrinsic area; and
a filter layer disposed over the second conductivity type semiconductor layer and configured to selectively allow only light of a specific wavelength to pass through and be received by the intrinsic area so an electrical signal is generated correspondingly; and
a light-shielding sidewall completely covering a sidewall of the photodiode structure to block any light from passing through the sidewall and being received by the intrinsic area.

9. The photodiode of claim 8, wherein the light-shielding sidewall is an epoxy resin sidewall.

10. The photodiode of claim 8, wherein the light of a specific wavelength is an ultraviolet light.

11. The photodiode of claim 10, wherein the wavelength of the ultraviolet light is smaller than 400 nanometers (nm).

12. The photodiode of claim 8, wherein the filter layer is a band pass filer layer.

13. The photodiode of claim 8, further comprising an anti-reflective layer formed above the filter layer.
